(19) United States
(12) Patent Application Publication
(10) Pub. No.: US 2006/0066328 A1
(43) Pub. Date: Mar. 30, 2006

(54) Buckling beam probe test assembly

(75) Inventors: Scott Clegg, Scottsdale, AZ (US); Gary Luu, Livermore, CA (US)

Correspondence Address: STEPTOE & JOHNSON LLP, 201 EAST WASHINGTON STREET, SUITE 1600, PHOENIX, AZ, 85004, US

(73) Assignee: Probelogic, Inc.

(21) Appl. No.: 10/955,107

(22) Filed: Sep. 30, 2004

(51) Int. Cl. G01R 31/02

(52) U.S. Cl. 324/754

(57) ABSTRACT

A hybrid-buckling beam probe assembly is disclosed for probing semiconductor chips. The probe assembly includes an upper and lower die. A template is attached to a boss on the lower die. This template improves the reliability, time, and cost of assembling the hybrid-buckling beam probe assembly. In addition, the template facilitates on site repair and replacement of hybrid buckling beam probes that become damaged or worn during use. An optional spacer may be attached between the upper and lower dies. A template alignment tool is used to attach the template to the boss by means of adhesive strips.

### FIELD OF THE INVENTION

The present invention relates to the field of electrical testing devices for microchips, and more particularly to a hybrid-bucking beam probe test assembly for contacting a footprint of a chip.

### BACKGROUND OF THE INVENTION

Semiconductor chips are connected to external electronics through contact pads manufactured on the semiconductor chip. Wire bonding and flip-chip bonding are two of the most common methods of forming electrical connections between semiconductor chips and external electronics. In wire bonding, a plurality of bonding pads are located in a pattern on the top surface of the substrate. This pattern of bonding pads is referred to as the substrate's footprint. Fine wires, typically made from gold or aluminum, are connected between the contacts on the substrate and bonding pads formed in a microchip packaging. Flip-chip bonding is an efficient method of electrically coupling a chip to external electronics. In the flip-chip technique, the top surface of the semiconductor chip has an array of electrical contact pads. A solder bump is formed on each of the contact pads. The chip packaging has a corresponding grid or array of contact pads. The chip is flipped upside down so that the solder bumps on the chip mate with the grid of contact pads in the package, hence the name “flip-chip.” The assembly is heated to flow the solder plaiting on the chip contacts. As with wire bonding, the pattern of solder bump contacts on the chip is referred to as the footprint. With this array/grid of solder bumps, these chips are often called area-array solder-bump devices.

The profitability of microchip manufacturers is dependent upon the ability to test and probe semiconductor chips for quality assurance. Semiconductor chips are sometimes defective and it is undesirable for economic reasons to package defective chips as packaging often represents an expensive step in the fabrication of integrated circuits. Consequently, it is highly desirable to test semiconductor chips before they are packaged. In addition, testing semiconductor chips enables companies to maintain the reliability and quality in fabrication processes. Tesing the chips prior to packaging is often referred to as wafer probing. Wafer probing also enables manufacturers to work toward increasing the yield of its fabrication line, thereby improving profit margins.

The process of wafer probing is such that probes are used to establish electrical contact with the pads formed on the semiconductor chip. The probes are used to apply test voltages at the pads for testing the response of the semiconductor chip to determine whether it is defective. Semiconductor chips that pass the test are packaged and defective semiconductor chips are discarded.

Current trends in the microelectronic industry portend ever increasing chip densities, which translate in the need for new probing devices that can accommodate the increased number of contact pads formed on the chip.

Probing integrated circuits in the early days of the industry consisted of contacting a relatively small number of points on a chip. This fact is the case even today in applications such as in-line testing where resistance measurements are commonly made using 4-point probes. In general, however, the trend has been toward simultaneously contacting more and more points.

Testing of chips has placed increasing demands on testers and probe hardware. With linear and peripheral footprints it is possible to utilize commercially available contactors. Cantilever contacts are commonly used and well known for peripheral-type footprints. However, the advent of area array or matrix footprints has required the development of probing devices that can accommodate virtually any footprint.

Cast channel probes are one type of testing device for contacting a chip footprint. With a cast channel probe, remote miniature coil springs activate contact wires contained in fine tubing. However, this probe-type has high frequency and footprint limitations. Buckling beam probes using vertical wire columns is another type of testing device for contacting the footprint of an area array device. Buckling beam probes employ the principal of a buckling column, whereby the application of a force beyond the critical load causes buckling to occur. Lengths of 600 to 700 mils (0.6 to 0.7 inches, or 15 to 18 millimeters) are common for buckling beam probes. This long length of the buckling beam probes produces the electrical problem of a resultant inductance as well as signal crosstalk. Forming probes with a hybrid-buckling beam greatly reduces these electrical problems experienced with longer buckling beam probes. These hybrid-buckling beams are flattened and precurved, thereby allowing for a shorter probe length, thus reducing inductance and signal crosstalk. Hybrid-buckling beam probes are also known as COBRA probes, which is a registered trademark of Wentworth Laboratories, Inc., due to their cobra like shape.

Current hybrid-buckling beam probe assemblies suffer from many drawbacks. Fabricating a probe assembly commonly requires troublesome and problematic processes whereby the probes are glued to the probe assembly. In addition, the repair and replacement of damaged or worn probes typically requires the complete disassembly and reassembly of the entire probe assembly. There is therefore a need to improve the design of hybrid-buckling probe assemblies to address these problems and inter alia, improve the quality, function, cost, and manufacturability of hybrid-buckling beam probe assemblies.

### SUMMARY OF THE INVENTION

The present invention is an improved hybrid-buckling beam probe assembly for probing semiconductor chips. The probe assembly includes an upper and lower die. A template is attached to a boss on the lower die. This template improves the reliability, time, and cost of assembling the hybrid-buckling beam probe assembly. In addition, the template facilitates on site repair and replacement of hybrid buckling beam probes that become damaged or worn during use. An optional spacer may be attached between the upper and lower dies. A template alignment tool is used to attach the template to the boss.

### BRIEF DESCRIPTION OF THE DRAWINGS

FIG. 1 illustrates an exploded view of a hybrid-buckling beam probe assembly.

FIG. 2 illustrates a pair of hybrid-buckling beam probes, one with a flat end and one with a pointed end.

FIG. 3 illustrates a sectional view of the probe assembly with a spacer.

FIG. 4 illustrates a sectional view of the probe assembly.

FIG. 5 illustrates a perspective view of an assembled hybrid-buckling beam probe.

FIG. 6 illustrates a bottom perspective view of the upper die.

FIG. 7 illustrates a bottom perspective view of the lower die.

FIG. 8 illustrates flow chart depicting a process for assembling the probe assembly.

FIG. 9 illustrates a perspective view of a template alignment tool.

FIG. 10 illustrates a partially assembled hybrid-buckling beam probe assembly on an assembly stand with the template alignment tool.

FIG. 11 illustrates a top view of a template alignment tool with a template.

FIG. 12 illustrates a probe assembly with the upper die removed where the probes are held in place by the template.

FIG. 13 illustrates a flow chart depicting a process for replacing a hybrid-buckling beam probe in the assembly for maintenance and repair.

FIG. 14 illustrates a portion of a probe assembly in contact with a printed circuit board and a solder bump on a wafer.

FIG. 15 illustrates a perspective cut-away view of a probe assembly.

FIG. 16 illustrates a perspective cut-away view of a probe assembly.

### DETAILED DESCRIPTION OF THE PREFERRED EMBODIMENTS

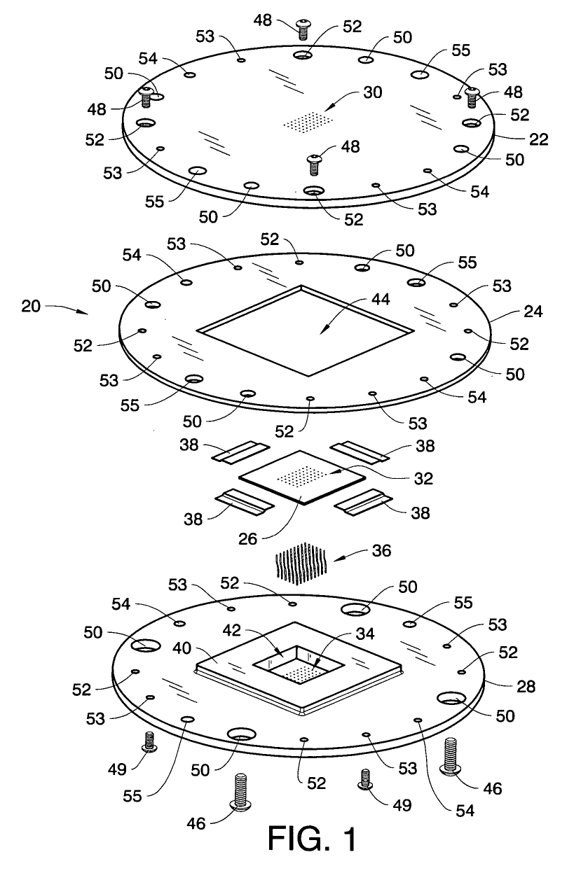

Referring to the Figures by characters of reference, FIG. 1 illustrates an exploded view of a preferred hybrid-buckling beam probe assembly 20. Hybrid-buckling beam probe assembly 20 includes an upper die 22, a spacer 24, a template 26, and a lower die 28. Upper die 22 is provided with a patterned array of micro-holes 30. Template 26 is provided with a patterned array of micro-holes 32. Lower die 28 is also provided with a patterned array of micro-holes 34. Patterned arrays of micro-holes 30, 32, and 34 are provided so that upper die 22, template 26, and lower die 28 may receive a plurality of hybrid-buckling beam probes 36. Patterned arrays of micro-holes 30, 32, and 34 are configured so that probes 36 are positioned to make electrical contact with solder bumps on a semiconductor chip. Micro-holes 30, 32, and 34 are formed in upper and lower dies 22 and 28, and template 26 typically by laser drilling, machine drilling, or photoetching.

An upper portion of hybrid-buckling beam probes 36 extend through micro-holes 32 formed in template 26 up into micro-holes 30 formed in upper die 22. Hybrid-buckling beam probes 36 protrude from the top surface of upper die 22 through micro-holes 30. A lower portion of hybrid buckling beam probes 36 extend down through micro-holes 34 such that they protrude from the bottom surface of lower die 28.

Template 26 is attached to lower die 28 in one exemplary method with adhesive strips 38. Other methods of attaching template 26 to lower die 28 include ultrasonic welding, adhesive glue, mechanical fasteners, or other conventional means of attachment known to the art. Lower die 28 has a boss 40 formed therein. Boss 40 is a raised rectangular area that defines a rectangular cavity 42. The rectangular shape of boss 40 is merely exemplary and boss 40 may be formed in other geometric configurations that are capable of providing a raised surface for supporting template 26. While boss 40 is illustrated as being molded into lower die 28, boss 40 may be a separate component that is attached to lower die 28. Boss 40 functions as a raised surface to support template 26. Template 26 is attached to the top surface of boss 40 in one exemplary method with adhesive strips 38. Adhesive strips 38 extend partially over both the top surfaces of boss 40 and template 26, thereby attaching template 26 to boss 40. When template 26 is attached to boss 40, rectangular cavity 42 becomes an enclosed chamber with hybrid-buckling beam probes 36 protruding therefrom. Hybrid-buckling beam probes 36 are held in relative position within rectangular cavity 42 by template 26 and lower die 28. Hybrid-buckling beam probes 36 are made of a conductive material. Hybrid-buckling beam probes 36 may be formed from wire or etched from a sheet of conductive material. The wire or conductive material may be copper, gold, gold-plated copper, copper-plated steel, gold-plated steel, or the like. Other exemplary materials for the probes are PALINEY 7, which is a registered trademark of the J.M. Ney Company, or BeCu. In a nanotechnology implementation, probes 36 could be nanotubes. MEMS is another implementation where the probes are formed by electro-plating methodologies.

Spacer 24 rests directly against the top surface of lower die 28 when probe assembly 20 is assembled. Spacer 24 is provided with a rectangular opening 44 that allows boss 40 to protrude up through spacer 24.

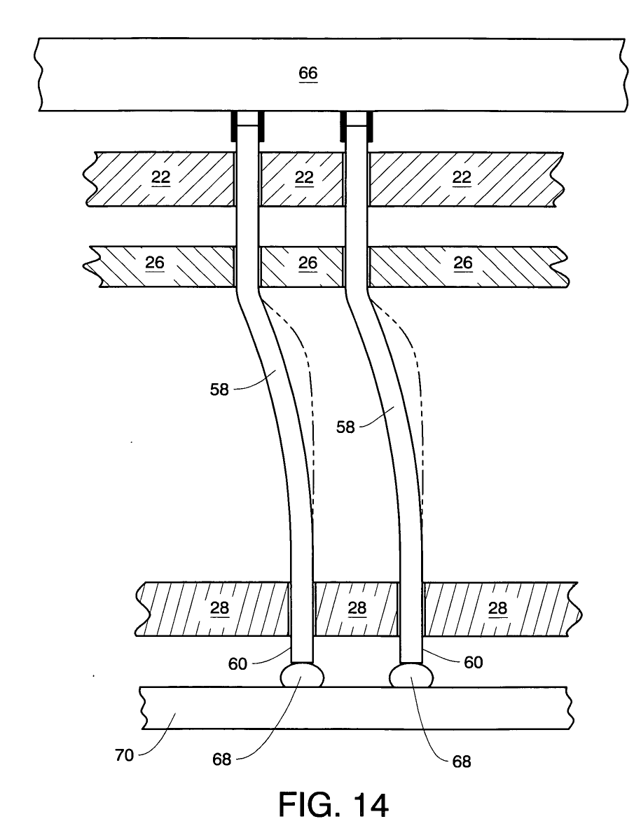

Hybrid-buckling beam probe assembly 20 is used for probing semiconductor chips 70, as shown in FIG. 14. Hybrid-buckling beam probes 36 protrude from the bottom surface of lower die 28 in order to make electrical contact with the solder bumps 68 forming the footprint of semiconductor chip 70, illustrated in FIG. 14. An individual hybrid-buckling beam probe 36 contacts each individual solder bump 68. Hybrid-buckling beam probes 36 protrude from the upper surface of upper die 22 in order to contact a printed circuit board 66, illustrated in FIG. 14, mounted to the top portion of hybrid-buckling beam probe assembly 20. The electrical operation of printed circuit board 66 sends current through hybrid-buckling beam probes 36 to semiconductor chip 70 via the individual solder bumps 68 in contact with each individual probe 36, thereby enabling a test to determine if the semiconductor chip is defective.

Screws 46 attach probe assembly 20 to printed circuit board 66. Screws 48 attach upper die 22 and spacer 24 together. Screws 49 attach lower die 28 and spacer 26 together. Holes 50 are provided in upper die 22, lower die 28, and spacer 24 for screws 46 to attach probe assembly 20 to the printed circuit board 66. Holes 52 are provided in upper die 22 and spacer 24 for screws 48 to attach upper die 22 to spacer 24. Holes 53 are provided in lower die 28 and spacer 24 for screws 49 to attach lower die 22 to spacer 24.

Hybrid-buckling beam probe assembly 20 is used repeatedly to test numerous semiconductor chips. During this testing, probe assembly 20 may require cleaning or repair. It therefore becomes desirable to have the ability to remove probe assembly 20 from printed circuit board 66. It is also desirable to have the ability to disassemble probe assembly 20 in order to gain access to damaged or worn probes 36 for replacement. Machine screws 46 are used in order to allow for the repeated removal and reattachment of probe assembly 22 to the printed circuit board 66. Machine screws 48 and 49 allow for the repeated disassembly and reassembly of probe assembly 20 for maintenance.

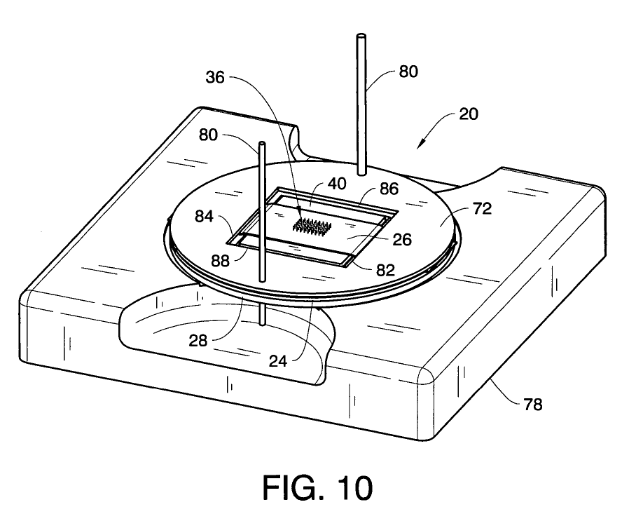

Gauge pins 80, illustrated in FIG. 10, are used to place upper die 22, spacer 24, and lower die 28 in alignment during assembly. Gauge pins 80 extend through gauge pin holes 54 formed in upper die 22, spacer 24, and lower die 28. Once upper die 22, spacer 24, and lower die 28 are attached together with screws 48 and 49, gauge pins 80 are preferably removed, but they could be left in place if pressed into one of the dies. A pair of holes 55 is also provided in upper die 22, spacer 24, and lower die 28 for the attachment of an optional protective cover to probe assembly 20 with a pair of machine screws. As an alternative to the use of gauge pins 80, upper die 22, spacer 26, and lower die 28 may have alignment flats on their respective outer circumferences to facilitate the mass-assembly.

A preferred material for template 26 is a polyimide, such as KAPTON, which is a registered trademark of DuPont. Other various plastics familiar to those in the art may be used to form template 26, such as polymethyl methacrylate (commonly known as LUCITE or PLEXIGLAS), polystyrene, NYLON, or polyethylene. A preferred material for adhesive strips 38 is KAPTON tape. However, other adhesive strips know to the art for attaching KAPTON or various other plastics to the top surface of boss 40 may be used. Other methods of attaching template 26 to lower die 28 include ultrasonic welding, adhesive glue, mechanical fasteners, or other conventional means of attachment known to the art.

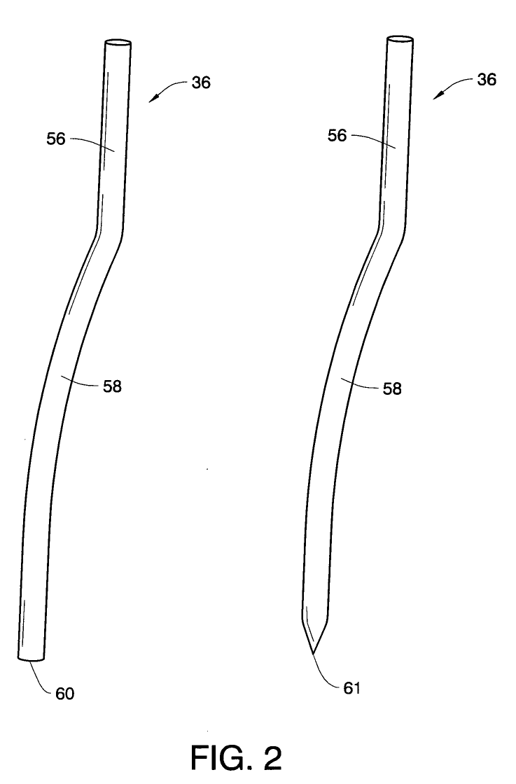

FIG. 2 illustrates a hybrid-buckling beam probe 36 with a flat end 60 and a hybrid-buckling beam probe 36 with a pointed end 61. Both hybrid-buckling beam probes have a probe head 56 that extends through micro-holes 32 formed in template 26 and micro-holes 30 formed in upper die 22. Precurved beam 58 extends through micro-holes 34 formed in lower die 28. Probe 36 may be provided with a flat contact head 60 or a pointed contact head 61. Probes 36 are a hinged-offset hybrid column. Precurved beam 58 functions as the active flexing portion of probe 36. Probes 36 may have an exemplary length of 250 mils+/−1 mils when made from 5 mil wire, 220+/−1 mil for 4 mil wire, or 170+/−1 mil for 3 mil wire.

The solder bumps 68 in semiconductor chip 70 will have slight variations in height. Probes 36 are able to buckle and bend allowing contact head 60/61 to move perpendicular to the plane of the semiconductor chip 70 and solder bumps 68 on it. Probes 36 are placed into contact with the solder bumps 68 by aligning probes 36 with the footprint of chip 70. Probe assembly 20 is then pressed down against the footprint of chip 70. Probes 36 that come into contact with taller solder bumps 68 will place an upward force against those probes 36 causing them to buckle and move upward, thereby allow the other probes 36 to come into contact with the shorter solder bumps 68. Thus, probe 20 accommodates height discrepancies between solder bumps 68.

Hybrid-buckling beam probes 36 acquired this name due to their mechanical behavior. Probe assembly 20 functions upon the basic buckling beam principle of mechanics. This principle is based on mathematical equations that define the bending, or buckling, of columns as a function of loads placed on them and the geometry of the columns. These relationships, when applied to buckling beams, show that when a force is placed on contact head 60/61 of probe 36, that probe 36 will bend and generate a spring force that is generally independent of the amount of vertical displacement of contact head 60/61. As a result, it is possible to press an array of probes 36 against the footprint of chip 70 such that all probes 36 contact all solder bumps 68 with a relatively uniform amount of force between each probe 36 and solder bump 68, thereby enabling probe assembly 20 to be used to perform quality tests upon semiconductor chip 70.

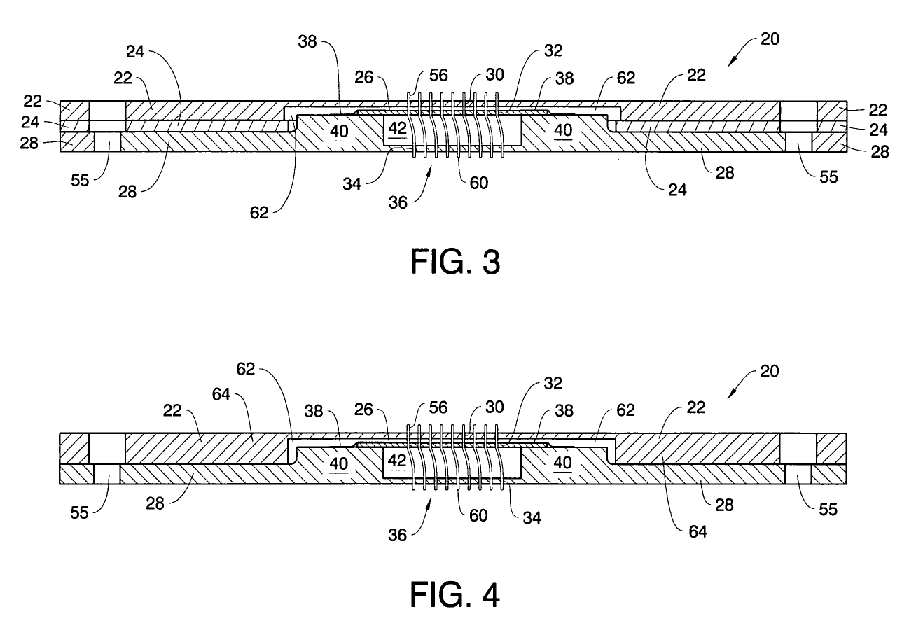

FIG. 3 illustrates a sectional view of probe assembly 20 with spacer 24. Probe assembly 20 is shown assembled in FIG. 3. Holes 55 receive screws for attaching probe assembly 20 to a protective cover. Lower die 28 has boss 40 formed therein. Boss 40 provides a platform upon which template 26 is attached in one exemplary method with adhesive strips 38. Other methods of attaching template 26 to lower die 28 include ultrasonic welding, adhesive glue, mechanical fasteners, or other conventional means of attachment known to the art. Together, boss 40 and template 26 define cavity 42. Upper die 22 has a recess 62 formed therein. Recess 62 provides space for template 26 and the method used to attach template 26 to boss 40, such as adhesive strips 38.

Probe heads 56 extend through micro-holes 30 and protrude above the top surface of upper die 22. Contact heads 60/61 then contact solder bumps 68 formed on the printed circuit board 66. Normal electrical current flowing through chips 70, which are connected to printed circuit board 66 via solder bumps 68, provides test current to probe assembly 20 for the testing of semiconductor chips 70. Probe heads 56 also extend through micro-holes 32 formed in template 26. Contact heads 60/61 of probes 36 extend through micro-holes 34 formed in lower die 28 and protrude below the bottom surface of lower die 28. Precurved beams 58 of probes 36 are able to buckle or bend within cavity 42, thereby allowing contact heads 60/61 to move vertically within micro-holes 34. In addition, each probe 36 is capable of independently buckling, thereby allowing each contact head to have a different amount of vertical displacement as probe assembly 20 is placed in contact with the area array of solder bumps. As a result, probe assembly 20 can form contact between all probes 36 and all solder bumps 68 in the footprint when the solder bumps 68 are not uniformly flat.

It is desirable to form micro-holes 36 in the region of upper die 22 which has recess 62, due to the fact that the thickness of upper die 22 is less within recess 62 than in the remainder of upper die 22. Having this thinner surface within recess 62 improves the ability to manufacture micro-holes 30 and assemble probes 36 with upper die 22. Micro-holes 34 are also formed in a thinned surface of lower die 28. Cavity 42 formed within boss 40 is created such that the bottom surface is thinner than the remainder of lower die 28 in order to support micro-holes 34. The thinned central bottom portion of lower die 22 within cavity 42 has a thickness less than the outer portions of lower die 22. It is desirable to have micro-holes 34 formed in the thinned surface of lower die 22 to help facilitate the movement of contacts 58 as probes 36 buckle, bend, and move when probing a solder bump device. The thinned surface of lower die 28 within cavity 42 also aids in the manufacture and assembly of microholes 34 with probes 36. These microholes may be laser drilled, machine drilled, or photoetched.

FIG. 4 illustrates a sectional view of probe assembly 20. In this alternative embodiment, upper die 22 is made thicker with regions 64 in order to eliminate spacer 24, thereby creating a two piece body made from upper die 22 and lower die 28. Regions 64 of upper die 22 rest directly against lower die 28. Recess 62 formed in upper die 22 is configured to provide room for boss 40, template 26, and the method used to attach template 26 to boss 40, such as adhesive strips 38.

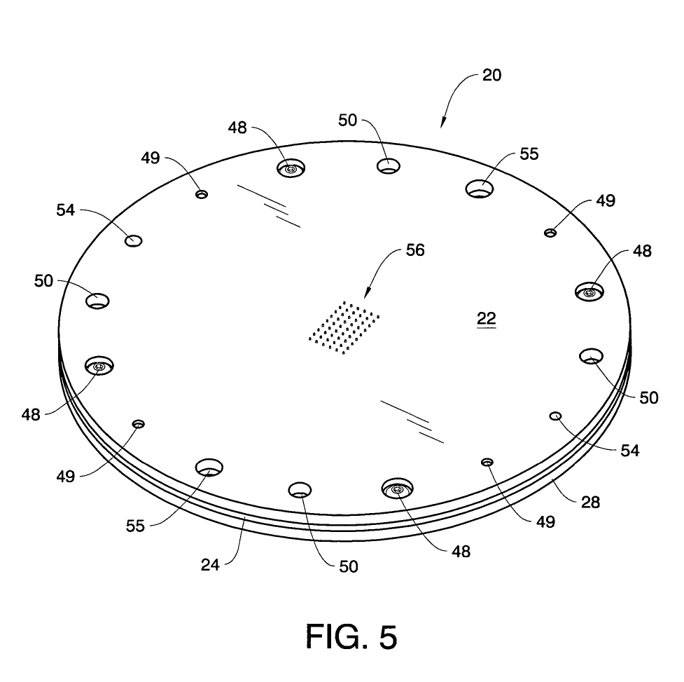

FIG. 5 illustrates a perspective view of an assembled hybrid-buckling beam probe 20. Upper die 22, spacer 24, and lower die 28 are joined together by machine screws 48 and 49, thereby forming an exemplary body that is a flat disc. The exterior shape of the probe head can also take the form of a square, rectangular, oval, or other geometric shape. Heads 56 of probes 36 protrude above the top surface of probe assembly 20. Probe heads 56 protrude above upper die 22 in order to make electrical contact with printed circuit board 66 for probing of the solder bumps 68 of semiconductor chip 70. Upper die 22, spacer 24, and lower die 28 are joined together in alignment through use of gauge pins 80 that are positioned in holes 54. Holes 50 receive machine screws 46 that attach probe assembly 20 to the printed circuit board 66. Holes 55 receive screws that attach the protective cover over probe assembly 20.

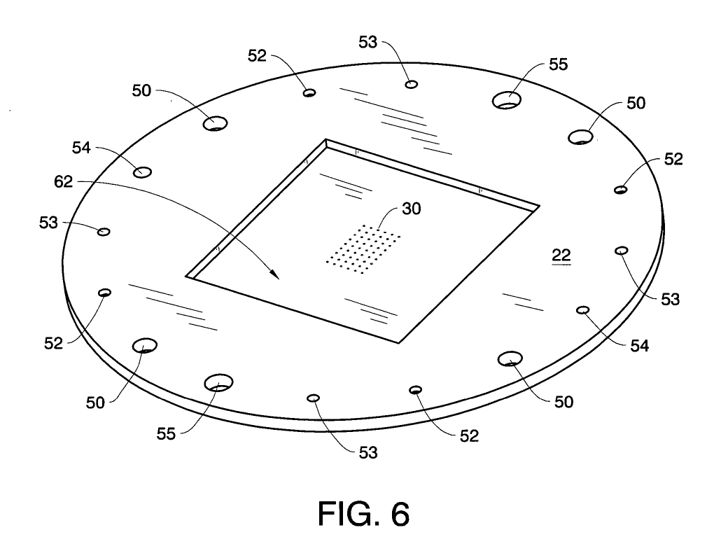

FIG. 6 illustrates a bottom perspective view of upper die 22. Upper die 22 is provided with recess 62. Recess 62 provides space for template 26 and the method used to attach template 26, such as adhesive strips 38 within the interior of probe assembly 20. Other methods of attaching template 26 to lower die 28 include ultrasonic welding, adhesive glue, mechanical fasteners, or other conventional means of attachment known to the art. In addition, recess 62 provides clearance for boss 40 to extend up into upper die 22. Micro-holes 30 are formed in that portion of upper die 22 which has recess 62. It is desirable to form micro-holes 36 in recess 62 due to the fact that the thickness of upper die 22 is less within recess 62 than in the remainder of upper die 22, thereby enhancing the manufacture, assembly, and operation of probe assembly 20. Upper die 22 has holes 50, 52, 54, and 55 formed therein to receive machine screws 46, 48, 49, gauge pins 80, and protective cover screws respectively.

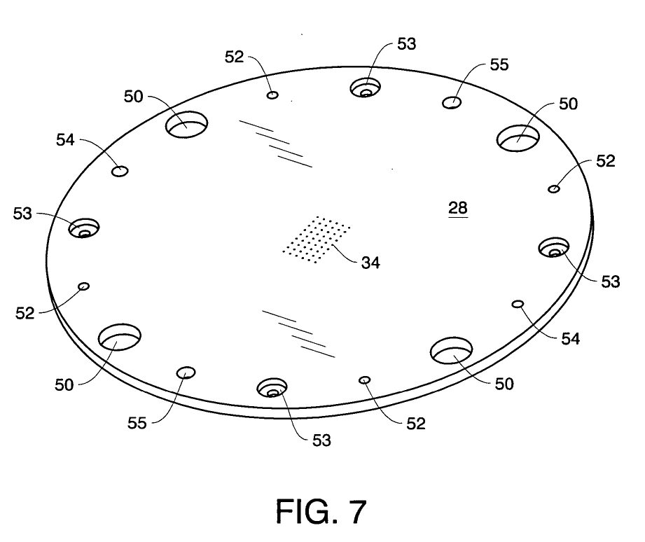

FIG. 7 illustrates a bottom perspective view of lower die 28. Micro-holes 34 are formed in lower die 28 so that contact heads 60/61 of probes 36 may extend and protrude from the bottom surface of lower die 28 and make electrical contact with the solder bumps 68 in semiconductor chip 70. Lower die 28 has holes 50, 52, 54, and 55 formed therein to receive screws 46, 48, 49, gauge pins 80, and protective cover screws respectively.

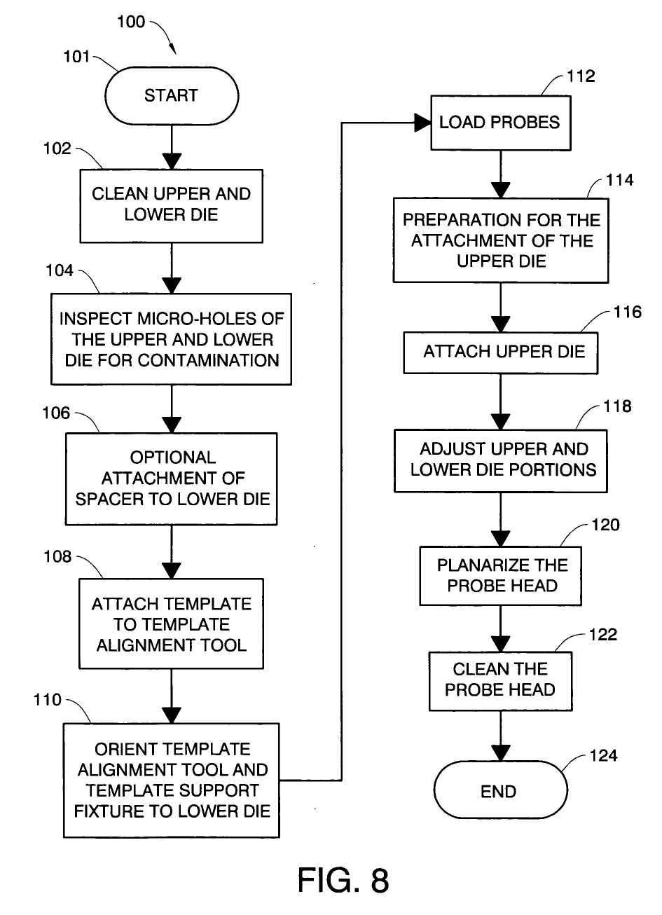

FIG. 8 illustrates flow chart depicting process 100 for assembling probe assembly 20. Starting the assembling process with step 101, upper and lower dies 22 and 28 and spacer 24 are cleaned in step 102. This cleaning typically uses compressed air to remove larger debris. Because upper and lower dies 22 and 28 and spacer 24 may have other surface contaminants, the surfaces are also cleaned with a mild solvent, like isopropyl alcohol. In step 104, micro-holes 30, 32, and 34 are then inspected for debris and they may be sent back to step 102 for further cleaning. Spacer 24 may be optionally attached to upper die 22 in step 106 in order to form the preferred embodiment depicted in FIG. 3. In step 106, spacer 24 and lower die 28 are positioned so that holes 54 are in alignment. For the alternative embodiment depicted in FIG. 4 that does not employ a spacer 24, step 106 is skipped. Gauge pins 80, illustrated in FIG. 10, may then be inserted into holes 54 of lower die 28 and spacer 26 in order to position and hold lower die 28 and spacer 26 in relative alignment. Machine screws 49 are then employed to attach lower die 28 to spacer 24 through holes 52.

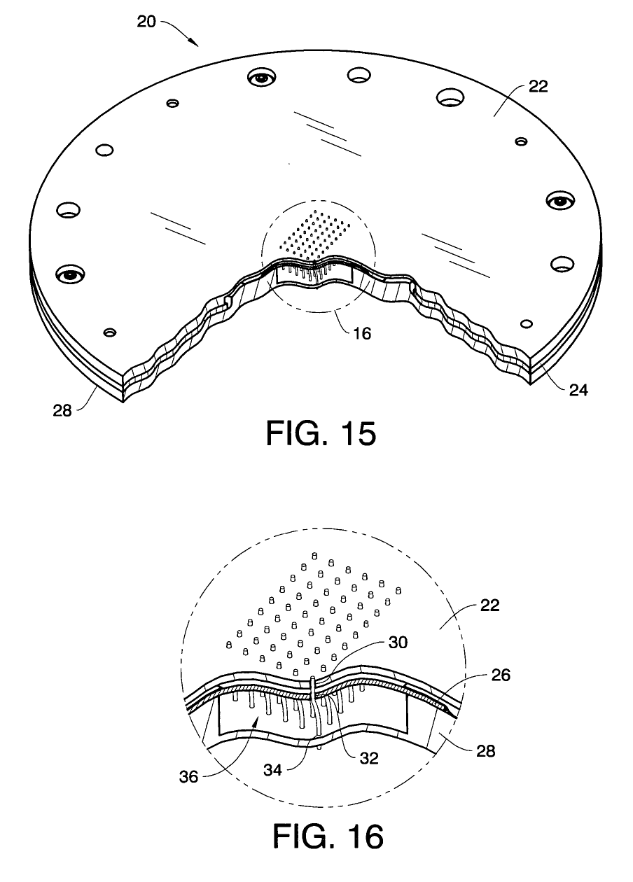

In step 108, template 26 is attached to a template alignment tool 72, illustrated in FIG. 15, that supports the positioning of template 26 to lower die 28. In this step, lower die 28 and spacer 24 are placed in a support fixture 78, illustrated in FIG. 10. In step 110, template alignment tool 72 is then placed in alignment with lower die 28 such that micro-holes 32 and 34 are aligned. Template alignment tool 72 is then clamped to the lower die 28. In step 112, probes 36 are loaded into probe assembly 20. Probes 36 are generally handled with tweezers. Contact heads 60/61 of probes 36 are inserted into micro-holes 32 of template 26 and are pushed down until they extend through micro-holes 34. Compressed air can be used to remove any debris from probe assembly 20 during this probe 36 loading process.

Preparation for the attachment of upper die 22 is made in step 114. First, template alignment tool 72 is unclamped from lower die 28. Template alignment tool 72 is then rotated to determine if all of probes 36 loaded into probe assembly 20 can move freely. Probes 36 that do not move freely are worked on further until they can move freely, or they are replaced with other probes 36. Probes 36 that cannot move freely are unable to buckle and flex when normally when placed in contact with the semiconductor chip 70, thereby preventing assembly 20 from functioning normally. Once all probes 36 move freely, template alignment tool 72 is moved back into the position where micro-holes 32 and 34 are in relative alignment using gauge pins 80 inserted in holes 54. Template alignment tool 72 is then re-clamped to lower die 28. Template 26 is then attached to lower die 28, such as by use of adhesive strips 38, which are typically KAPTON tape. Other methods of attaching template 26 to lower die 28 include ultrasonic welding, adhesive glue, mechanical fasteners, or other conventional means of attachment known to the art. Template 26 is then separated from template alignment tool 72.

Upper die 22 is then attached to spacer 24 and lower die 28 in step 116. Upper die 22 is carefully lowered and moved into position so that heads 56 of probes 36 extend up through micro-holes 30 formed in upper die 22. In step 118, gauge pins 80 are inserted through holes 54 in upper die 22, spacer 26, and lower die 28 in order to place upper die 22, spacer 26, and lower die 28 in relative alignment. Screws 48 then join upper die 22 to spacer 26 and lower die 28 creating assembled probe assembly 20.

Contact heads 60/61 of probes 36 are then planarized in step 120 so that contact heads 60/61 are on a generally uniform plane for making contact with the footprint of semiconductor chips 70. Collectively, all of contact heads 60/61 are referred to as the probe head. Lapping fixtures are one exemplary method of planarizing contact heads 60/61. In step 122, the probe head is cleaned. An ultrasonic clean process with isopropyl alcohol is one exemplary method of cleaning contact heads 60/61. The assembly process is then complete and ends in step 124.

The use of template 26 and boss 40 presents numerous advantages. Having the ability to attach template 26 to boss 40 with adhesive strips 38, for example, eliminates the need to use glue in assembling probe assembly 20. Glue is commonly used to hold probes 36 in position within lower die 22 during attachment of upper die 22. The use of solvent to clean probe assembly 20 does not always result in the freeing all glued probes, consequently requiring a rebuild or scrapping of those assemblies 20. The use of template 26 eliminates these costly and problematic glue steps and allows for a more reliable and cost effective assembly process.

The use of template 26 also helps to secure probes 36 during the assembly process. Without template 26, probes 36 can slip out of lower die 28 more easily, requiring reassembly of probe assembly 20, thereby adding cost to the device. However, template 26 helps to hold probes 36 in position during attachment of upper die 22, thereby making for a more reliable manufacturing process. The use of the template 26 and boss 40 also facilitates repair. Together, template 26 and boss 40 enable the repair and replacement of a damaged probe 36 without the entire disassembly and reassembly as discussed later in more detail.

The use of template 26 also simplifies the attachment of upper die 22 to the remainder of probe assembly 20. Template 26 places probes 36 in alignment with micro-holes 30 formed in upper die 30. Consequently, placing upper die 22 onto probe assembly 20 becomes simple and straightforward with holes 30 and 32 in alignment.

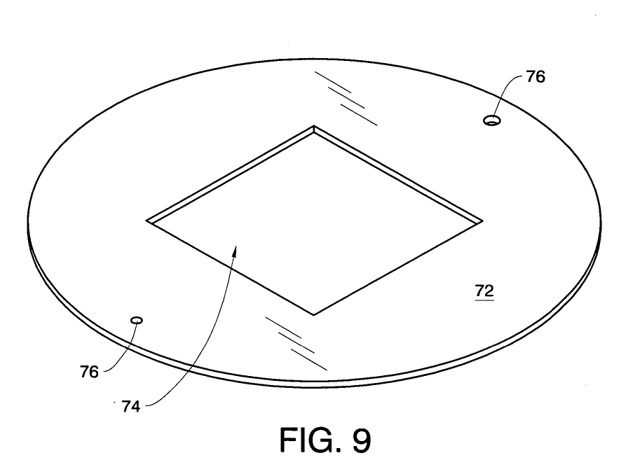

FIG. 9 illustrates a perspective view of template alignment tool 72. Template alignment tool 72 is provided with an opening 74 in which to receive template 26. Template alignment tool 72 is also provided with alignment holes 76 that receive gauge pins 80 in order to align template alignment tool 72 with lower die 28.

FIG. 10 illustrates a partially assembled hybrid-buckling beam probe assembly 20 on a assembly stand 78 with template alignment tool 72. Assembly stand 78 is configured to support the assembly of lower die 28, upper die 22, template 26, and buckling beam probes 36, optionally with spacer 24. Gauge pins 80 place lower die 28, upper die 22, and spacer 24 in alignment during assembly. Gauge pins 80 are also used to place template alignment tool 72 in alignment with lower die 22 and spacer 24 if added. Template 26 is placed within opening 74 of template alignment tool 72. Template alignment tool 72 constrains template 26 on two sides, 82 and 84. There is space provided between two sides, 86 and 88, of template 26 and template alignment tool 72. This space on sides 86 and 88 allows template 26 to slide laterally within template alignment tool 72, thereby facilitating the insertion of probes 36 during the assembly process 100. Allowing template 26 to slide laterally during assembly process 100 makes it easier to insert probes 36 through micro-holes 32 and 34 with tweezers. In addition, the space on sides 86 and 88 allows the application of adhesive strips 38 to template 26 and boss 40. Once adhesive strips 38 are applied to template 26 and boss 40, thereby attaching template 26 to boss 40, template alignment tool 72 is removed.

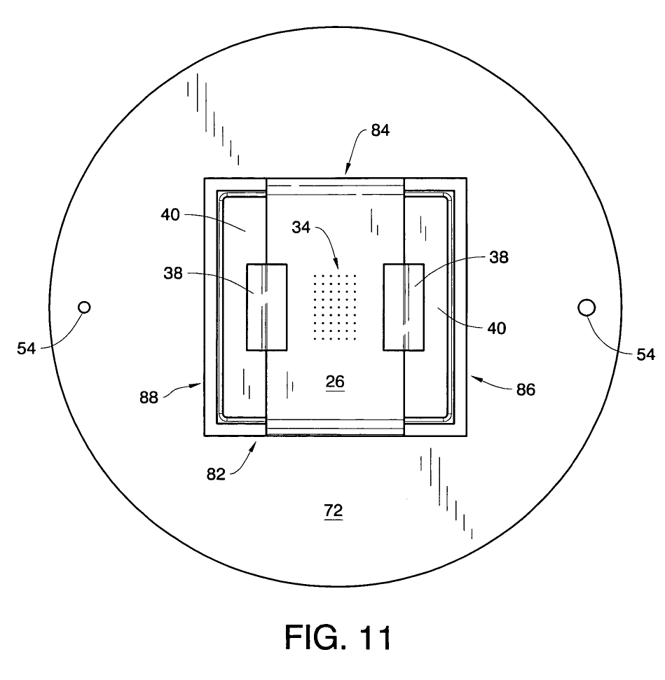

FIG. 11 illustrates a top view of a template alignment tool 72 with a template 26. Template alignment tool 72 restrains template 26 on two sides 82 and 84. There is space between template alignment tool 72 and template 26 on sides 86 and 88, thereby allowing template 26 to move along one axial direction within opening 74 of template alignment tool 72. In addition, the space on sides 86 and 88 allows for adhesive strips to be applied to template 26 and boss 40.

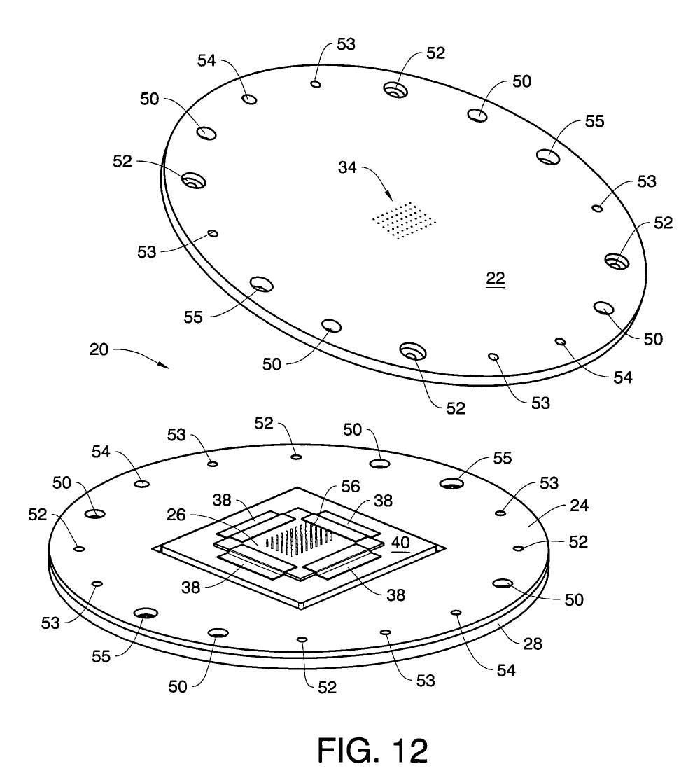

FIG. 12 illustrates probe assembly 20 with upper die 22 removed where probes 36 are held in place by template 26. Probe assembly 20 is used repeatedly to test semiconductor chips. During probing, it is common for probes 36 to become damaged. Probe assembly 20 is forcibly pressed against semiconductor chips in order to electrically test the solder bump devices. During this probing, probes 36 may become bent or jammed, thereby requiring replacement. Further, defective chips 70 may overdraw current through probes 36, causing probes 36 to break like a fuse. Alternatively, probes 36 may become worn during use. Contact heads 60 and 61 are repeatedly cleaned and planarized during the lifespan of probe assembly 20. This repeated cleaning and planarization can wear down probes 36 down to a point where one or more probes 36 require replacement. Removing screws 48 from probe assembly 20 allows for the removal of upper die 22. Screws 49 hold lower die 28 and spacer 24 together. When upper die 22 is removed, template 26 continues to hold probes 36 in position. Consequently, with a pair of tweezers, an operator can perform an on-site repair by pulling out the damaged or worn probes 36 and replacing them with new probes 36. Without template 26, probes 36 would easily fall out of lower die 28, consequently requiring the entire rebuilding of probe assembly 20 at the assembly facility. The use of template 24 and boss 40 therefore greatly reduces repair time and cost and allows for customers to repair the probe assemblies 20 on site instead of having to return them to the manufacture for a complete reassembly.

Template 26 is held down against boss 40 with, for example, adhesive strips 38. Heads 56 of probes 36 protrude up through the top surface of template 26. Boss 40 resides in the opening 44 of spacer 24. Screws 48 secure spacer 24 to lower die 28.

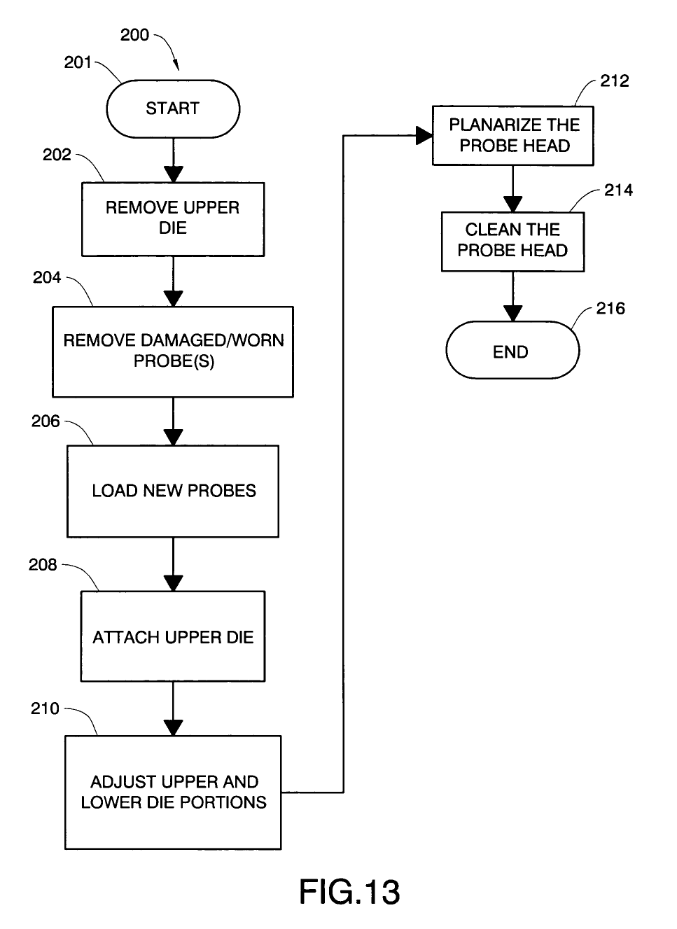

FIG. 13 illustrates a flow chart depicting process 200 for replacing hybrid-buckling beam probes 36 in assembly 20 for maintenance and repair. The repair process to replace damaged or worn probes 36 beings with step 201. Upper die 22 is removed from probe assembly 20 by removing screws 48 in step 202. Removing upper die 22 does not cause probes 36 to fall out of alignment in probe assembly 20 due to the attachment of template 26 to boss 40. It is then possible to remove the worn or damaged probes individually with tweezers in step 204. Probes 36 are removed by pulling on probe head 56 with tweezers and pulling the entire probe 36 through micro-holes 34 and 32 until it is completely removed from probe assembly 20. New probes 36 may then be loaded in step 206 with tweezers. New probes 36 are loaded into probe assembly 20 by grasping a probe 36 with tweezers and pressing contact head 60/61 down through micro-holes 32 and 34 until probe 36 protrudes out through the bottom of lower die 22. Steps 204 and 206 are repeated until all damaged and worn probes are replaced. In step 208, upper die 22 is reattached to probe assembly 20. In step 210, gauge pins 80, are inserted into holes 54 formed in upper die 22, lower die 28 and spacer 24 so that all three pieces are properly aligned. Once aligned, screws 48 are tightened to attach upper die 22 to the remainder of probe assembly 20. In step 212, contact heads 60 of probes 36 are planarized. Collectively, all of contact heads 60/61 are collectively referred to as the “probe head.” Once probes 36 are planarized, probes 36 and probe assembly 20 are cleaned in step 214. The process then ends in step 216.

FIG. 14 illustrates a portion of probe assembly 20 in contact with Printed Circuit Board (PCB) 66 and a solder bump 68 on a wafer 70. Probe 36 is held in relative position within probe assembly 20 by micro-holes 30, 32, and 34 in upper die 22, template 26, and lower die 28. While held in relative position, precurved beam 58 of probe 36 is able to buckle and bend within cavity 42, enabling contact head 60 to move vertically. Head 56 of probe 36 is electrically coupled to printed circuit board 66. Contact head 60 of probe 36 is in electrical contact with solder bump 68 formed on wafer 70 that is a portion of a semiconductor chip. PCB 66 provides current that goes through probe 36 into solder bump 68 in order to probe and test the semiconductor chip for quality and reliability. Probe assembly 20 is pressed down onto wafer 70, such that probes 36 buckle and contact heads 60/61 are displaced vertically. The buckling of probe 36 is shown in FIG. 11 by the dashed lines.

FIG. 15 illustrates a perspective cut-away view of a probe assembly. Upper die 22 is attached to lower die 28 and spacer 24. Micro-holes 30, 32, and 34 formed in upper die 22, template 24, and lower die 28 hold probes 36 in relative position within probe assembly 20 while allowing them a degree of freedom to buckle and move in order to form electrical contact with solder bumps 68. The number and configuration of probes 36 in assembly 20 is merely exemplary. The number and configuration of probes 36 is dictated by the number and arrangement of solder bumps 68 on wafer 70 forming the area array.

Although the present invention has been described in detail, it will be apparent to those of skill in the art that the invention may be embodied in a variety of specific forms and that various changes, substitutions, and alterations can be made without departing from the spirit and scope of the invention. The described embodiments are only illustrative and not restrictive and the scope of the invention is, therefore, indicated by the following claims.

We claim:

1) A hybrid-buckling beam probe assembly, comprising:
an upper die;
a lower die having a boss, said boss defines a cavity;
a template attached to said boss; and
a plurality of buckling beam probes extending through said template up into said upper die and down through said lower die, said buckling beam probes buckle within said cavity, said upper die removably attaching to said lower die, said template and said lower die holding said plurality of buckling beam probes in relative position when said upper die is detached from said lower die.

2) The hybrid-buckling beam probe assembly of claim 1, further comprising a spacer attached between said upper die and said lower die, said boss extends into an opening formed in said spacer.

3) The hybrid-buckling beam probe assembly of claim 1, further comprising an adhesive strip attaching said template to said boss.

4) The hybrid-buckling beam probe assembly of claim 1, wherein said template is attached to said boss with an adhesive.

5) The hybrid-buckling beam probe assembly of claim 1, wherein said template is attached to said boss by a welding process.

6) The hybrid-buckling beam probe assembly of claim 1, wherein said template is attached to said boss with a mechanical fastener.

7) The hybrid-buckling beam probe assembly of claim 1, wherein said template remains attached to said boss when said upper die is detached from said lower die.

8) The hybrid-buckling beam probe assembly of claim 1, wherein a damaged buckling beam probe may be removed from said hybrid-buckling beam probe assembly by detaching said upper die from said lower die and pulling said damaged buckling beam probe out from said lower die and said template.

9) The hybrid-buckling beam probe assembly of claim 8, wherein a new buckling-beam is inserted through said template down into said lower die.

10) The hybrid-buckling beam probe assembly of claim 1, wherein said template and said upper die are each provided with an array of holes for receiving said buckling-beam probes.

11) The hybrid-buckling beam probe assembly of claim 1, wherein lower die is provided with an array of holes for receiving said buckling-beam probes.

12) The hybrid-buckling beam probe assembly of claim 11, wherein said array of holes is formed within a thinned central portion of said upper die.

13) The hybrid-buckling beam probe assembly of claim 11, wherein said array of holes is formed within said cavity.

14) The hybrid-buckling beam probe assembly of claim 1, wherein said boss extends up into a cavity formed in said upper die.

15) A probe assembly, comprising:
an upper die having a first array of holes formed therein,
a template with a second array of holes formed therein;
a lower die having a third array of holes formed therein, said lower die having a raised portion surrounding third array of holes, said template attaching to said raised portion; and
a plurality of probes extending through said first, second, and third array of holes, said upper die is detachably connected to said lower die.

16) The probe assembly of claim 15, wherein said template remains attached to said lower die when said upper die is detached from said lower die.

17) The probe assembly of claim 15, wherein said template and said lower die hold said plurality of probes in relative position when said upper die is detached from said lower die.

18) The probe assembly of claim 15, further comprising a spacer having an opening, said spacer attached between said upper die and said lower die, said raised portion of said lower die extends through said opening.

19) The probe assembly of claim 15, wherein said raised portion of said lower die extends into a cavity formed in said upper die.

20) The probe assembly of claim 15, wherein a damaged probe is removed from said probe assembly by detaching said upper die from said lower die and pulling said damaged probe out from said lower die through said template while said template and said lower die hold said plurality of probes in relative position, whereby detaching said upper die from said lower die disengages said upper die from said plurality of probes.

21) A process for replacing a damaged probe in a hybrid-buckling beam probe assembly, comprising the steps of:
detaching an upper die from a lower die, thereby disengaging said upper die from a plurality of probes engaged by said lower die and a template;
holding said plurality of probes in relative position with said template attached to said lower die;
extracting said damaged probe from said lower die through said template;
inserting a new probe into said lower die through said template;
reattaching said upper die to said lower die.

22) The process of claim 21, wherein said template is attached to a raised portion connected to said lower die.

23) The process of claim 21, wherein said template is attached to a boss connected to said lower die.

24) A process for loading a set of probes in a hybrid-buckling beam probe assembly, comprising the steps of:
placing a lower die on a assembly stand;
aligning a template alignment tool on said lower die, said template alignment tool having a rectangular window for receiving a template;
placing a template through the rectangular window onto a boss, said boss connected to said lower die; said template alignment tool engages said template on two sides, thereby constraining the movement of said template within the rectangular window along a first axial direction while allowing lateral movement along a second axial direction perpendicular to said first axial direction;
loading a plurality of probes through said template into said lower die;
attaching said template to said boss; and
removing said template alignment tool.

25) The process of claim 24, further comprising a step of sliding said template within the rectangular window while loading said probes.

26) The process of claim 24, further comprising a step of holding said probes with said template and said lower die without adhesive.

27) The process of claim 24, further comprising a step of attaching an upper die to said lower die, wherein said probes are pre-aligned by said template with an array of micro-holes formed in said upper die.

28) The process of claim 24, further comprising a step of rotating said template alignment tool with respect to said lower die in order check the ability for said probes to move.
